(19) United States
(12) Patent Application Publication
(10) Pub. No.: US 2015/0241498 A1
(43) Pub. Date: Aug. 27, 2015

(54) METHOD OF DETERMINING POSSIBLY-UNUSED ELECTRIC WIRE AND PROGRAM

(71) Applicant: YAZAKI CORPORATION, Tokyo (JP)

(72) Inventor: Jin Watanabe, Aichi (JP)

(21) Appl. No.: 14/707,677

(22) Filed: May 8, 2015

Related U.S. Application Data
(63) Continuation of application No. PCT/JP2013/080822, filed on Nov. 14, 2013.

(30) Foreign Application Priority Data
Nov. 14, 2012 (JP) 2012-250531

(51) Int. Cl. G01R 31/02

(52) U.S. Cl. CPC G01R 31/023

(57) ABSTRACT

An electric wire classified as an extra electric wire in any one of patterns and classified as a necessary electric wire in any one of the remaining patterns is determined to be a possibly-unused electric wire, and an electric wire classified as an extra electric wire in the entirety of the patterns is determined not to be a possibly-unused electric wire.

### CROSS REFERENCE TO RELATED APPLICATIONS

This application is a continuation of international patent application No. PCT/JP2013/080822 filed on Nov. 14, 2013 based on Japanese Patent Application No. 2012-250531 filed on Nov. 14, 2012, the contents of which are incorporated herein by reference.

### BACKGROUND OF THE INVENTION

1. Field of the Invention

The present invention relates to a method of determining whether there presents a possibly-unused electric wire among electric wires of a wire harness, and a program.

2. Description of the Related Art

JP-A-2011-137800 and JP-A-2011-180115 disclose a wire harness continuity inspection apparatus. The wire harness continuity inspection apparatus simulates a situation in which a wire harness with an arbitrary part number is assigned to each of regions (an engine compartment, a vehicle interior wall, a trunk compartment, and the like, and hereinafter, each of the regions being referred to as a divided region) into which the space of a vehicle is divided on a functional basis and in which a wire harness can be routed. In addition, the wire harness continuity inspection apparatus analyzes whether electric components (for example, a battery, an electronic control unit (ECU), and a drive machine) are connected to each other via electric wires of the wire harness routed in each of the divided regions.

The wire harness continuity inspection apparatus disclosed in JP-A-2011-137800 and JP-A-2011-180115 locates a starting point of a circuit line in auxiliary device wiring information, and from partial connector and wiring information, the wire harness continuity inspection apparatus locates an end portion of an electric wire, which corresponds to the starting point. For each circuit line, the wire harness continuity inspection apparatus determines whether the electric wire with the end portion, and the connection of an electric wire connected thereto is connected to an ending point of the circuit line in the auxiliary device wiring information, while tracing the electric wire with the end portion, and the connection of an electric wire connected thereto with reference to the partial connector and wiring information.

The wire harness continuity inspection apparatus disclosed in JP-A-2011-137800 and JP-A-2011-180115 has a plurality of candidates for the wire harness which can be routed in each divided region, that is, a plurality of part numbers of wire harnesses that can be routed in each divided region in the assignment of a routable wire harness to each divided region of a target vehicle, and the preparation of partial connector and wiring information. When the space of a vehicle is divided into three divided regions, and there are two candidates (that is, part numbers) present for the wire harness which can be routed in each of the divided regions, eight (2×2×2) partial connector and wiring patterns are prepared. It is determined whether the starting point and the ending point of an electric wire connecting electric components in the auxiliary device wiring information and the partial connector and wiring information coincide with those in the partial connector and wiring information, respectively.

### SUMMARY OF THE INVENTION

When a plurality of part numbers of wire harnesses can be routed in a divided region, a possibly-unused electric wire may exist among the plurality of part numbers of wire harnesses. Here, the cause for having the possibly-unused electric wire and the definition of the possibly-unused electric wire will be described with reference to FIGS. 6A to 6C. FIGS. 6A to 6C are diagrams illustrating states in which wire harnesses with the respective different part numbers are routed in the same vehicle.

As illustrated in FIG. 6A, the space of the vehicle is divided into three divided regions A, B, and C, a wire harness W1 with a part number A1 is routed in the divided region A, a wire harness W2 with a part number B1 is routed in the divided region B, and a wire harness W3 with a part number C1 is routed in the divided region C. In addition, an electric component E11 is installed in the divided region A, an electric component E21 is installed in the divided region B, and electric components E31 and E32 are installed in the divided region C.

Connectors C11 and Cab are respectively provided in end portions of an electric wire of the wire harness W1. The connector C11 is connected to the electric component E11, and the connector Cab is connected to a connector Cab in an end portion of the wire harness W2.

The connector Cab and connectors C21 and Cbc1 are respectively provided in the end portions of an electric wire of the wire harness W2. The connector Cab is connected to the connector Cab in the end portion of the wire harness W1, the connector C21 is connected to the electric component E21, and the connector Cbc1 is connected to a connector Cbc1 in an end portion of the wire harness W3.

The connector Cbc1 and a connector C31 are respectively provided in the end portions of one of two electric wires of the wire harness W3. The connector Cbc1 is connected to a connector Cbc1 in the end portion of the wire harness W2, and the connector C31 is connected to the electric component E31. The connector Cbc1 and a connector C32 are respectively provided in the end portions of the remaining one of the two electric wires of the wire harness W3. The connector Cbc1 is connected to the connector Cbc1 in the end portion of the wire harness W2, and the connector C32 is connected to the electric component E32.

Subsequently, the routing of the wire harnesses will be described with reference to FIGS. 6B and 6C. The space of the vehicle illustrated in FIGS. 6B and 6C is the same as in FIG. 6A. Similarly to FIG. 6A, the space of the vehicle is divided into three divided regions A, B, and C. First, the difference between FIG. 6A, and FIGS. 6B and 6C is that the electric component E32 is not installed in the divided region C illustrated in FIGS. 6B and 6C. When a plurality of grades can be offered, or optional functions can be selected for the same vehicle type, different electric components are installed on the same type of vehicle due to a difference in grade or the existence and non-existence of an optional function. The reason for the difference in the installed electric component between FIG. 6A and FIGS. 6B and 6C is because the vehicle types are the same, but the grades or the selected optional functions of the vehicles are different.

As illustrated in FIG. 6B, when the electric component E32 is not installed in the divided region C, one electric wire of the two electric wires of the wire harness W3 is not required for the electric component E32. At this time, it is possible to realize a circuit configuration for connecting the electric components of the vehicle by preparing a wire harness W3 with a part number C2 which does not include one electric wire connected to the electric component E32, and by routing the wire harness W3 in the divided region C.

However, since the number of combinations of the grades and the optional functions of the same type of vehicle is a very large number, when preparing the entirety of wire harnesses for each divided region, the wire harness being formed of a different configuration of electric wires for each combination and having a different part number, the part numbers of the wire harness proliferate considerably, and thereby costs for managing the part numbers increase. For this reason, typically, a general-purpose wire harness is prepared for each divided region in such a manner so as to include electric wires compatible for the entirety of a given number of combinations, and the general-purpose wire harness is properly used and routed for a designated grade and a selected optional function.

As illustrated in FIG. 6C, the electric component E32 is not installed in the divided region C; however, the wire harness W3 with the part number C1 including one electric wire for the electric component E32 is prepared and routed in the divided region C. In this case, the wire harness W3 has the same part number C1 as the wire harness W3 routed in the divided region C illustrated in FIG. 6A, and is equivalent to the general-purpose wire harness. It is also possible to realize a circuit configuration for connecting the electric components of the vehicle using the general-purpose wire harness.

However, when the general-purpose wire harness is routed in a divided region, as illustrated in FIG. 6C, the case may happen in which the wire harness includes an electric wire, but the electric wire does not have a target connected to one end or the opposite ends of the electric wire (in FIG. 6C, the connector Cbc1 of the wire harness W2 and the electric component E32 are equivalent thereto.). As such, there may exist an electric wire among a group of electric wires of a wire harness, which has a connection counterpart when being routed in a vehicle of a specification, but does not have a connection counterpart in a vehicle of another specification. In this description, this electric wire is defined as a “possibly-unused electric wire”. In the broad sense, the possibly-unused electric wire is defined as circuitry that includes a terminal and a connector provided in an end portion of the possibly-unused electric wire, and the circuit of the possibly-unused electric wire.

When the continuity of a circuit line is inspected using the wire harness continuity inspection apparatus disclosed in JP-A-2011-137800 and JP-A-2011-180115, first, the terminal of an arbitrary electric circuit is specified from the auxiliary device wiring information. Since the auxiliary device wiring information may not contain any information regarding an electric circuit connected to the possibly-unused electric wire, the possibly-unused electric wire does not become a continuity inspection target of the wire harness continuity apparatus disclosed in JP-A-2011-137800 and JP-A-2011-180115, which is a problem. In addition, even when the possibly-unused electric wire is a continuity inspection target, it becomes important in improving the accuracy of analysis to determine whether the possibly-unused electric wire is a true possibly-unused electric wire, or an electric wire that is assumed not to have a connection counterpart due to the inaccuracy of the auxiliary device wiring information and the partial connector and wiring information.

The present invention is made in light of those problems, and an object of the present invention is to provide a method and a program for determining a possibly-unused electric wire by which it is possible to specify a possibly-unused electric wire from a group of electric wires of a wire harness via analysis.

In order to achieve this object, a method and a program for determining a possibly-unused electric wire according to the present invention have the following configurations (1) to (3).

(1) A method of determining a possibly-unused electric wire, the method including:
a formation step of forming one pattern by assigning a wire harness with an arbitrary part number out of wire harnesses routed in each of divided regions into which a space of a vehicle is divided;
a classification step of classifying for each pattern a group of electric wires of a first wire harness assigned to a first divided region of the divided regions into a necessary electric wire having a connection counterpart in a second divided region adjacent to the first divided region among the divided regions, and into an extra electric wire not having a connection counterpart in the second divided region; and
a determination step of determining that an electric wire is a possibly-unused electric wire when the electric wire is classified as the extra electric wire in any one of the patterns and classified as the necessary electric wire in any one of the remaining patterns, and determining that an electric wire is not a possibly-unused electric wire when the electric wire is classified as the extra electric wire in entirety of the patterns.

(2) In the method of determining the possibly-unused electric wire described in the configuration (1), the determination step includes determining that an electric wire is a possibly-unused electric wire when the electric wire is classified as the extra electric wire for the first wire harness with a predetermined part number assigned to one or a plurality of the patterns and classified as the necessary electric wire for the first wire harness with the predetermined part number assigned to one or a plurality of the remaining patterns.

(3) A program that causes a computer to execute each step in the method of determining the possibly-unused electric wire described in the configuration (1) or (2).

According to the method of determining a possibly-unused electric wire described in the configuration (1) or (2), and the program described in the configuration (3), it is possible to specify possibly-unused electric wires from a group of electric wires of a wire harness via analysis.

According to the method of determining a possibly-unused electric wire and the program of the present invention, it is possible to specify possibly-unused electric wires from a group of electric wires of a wire harness via analysis.

The present invention has been briefly described above. When an aspect (hereinafter, referred to as an embodiment) of embodying the present invention (to be described) is read through with reference to the accompanying drawings, the details of the present invention will become more apparent.

### BRIEF DESCRIPTION OF THE DRAWINGS

FIG. 1A shows tables illustrating recorded data after a continuity inspection phase for one pattern is completed, in a method of determining a possibly-unused electric wire according to an embodiment of the present invention.

FIG. 1B shows tables illustrating recorded data after a continuity inspection phase for another pattern is completed, in the method of determining a possibly-unused electric wire according to the embodiment of the present invention.

FIG. 2 is a diagram illustrating a possibly-unused electric wire detection phase in the method of determining a possibly-unused electric wire according to the embodiment of the present invention.

FIG. 3 is a diagram illustrating the possibly-unused electric wire detection phase in the method of determining a possibly-unused electric wire according to the embodiment of the present invention.

FIGS. 4A and 4B illustrate listed data when possibly-unused electric wires are determined.

FIG. 5 is a block diagram of an apparatus that executes the method of determining a possibly-unused electric wire according to the embodiment of the present invention.

FIGS. 6A to 6C are views illustrating when wire harnesses with different part numbers are respectively routed in the same type of vehicles.

### DETAILED DESCRIPTION OF THE EXEMPLARY EMBODIMENTS

Hereinafter, a specific embodiment of the present invention will be described with reference to the accompanying drawings.

A method of determining a possibly-unused electric wire according to the embodiment of the present invention will be described in detail. The method of determining a possibly-unused electric wire according to the embodiment of the present invention can be divided into two phases. A first phase is a continuity inspection phase, and a second phase is a possibly-unused electric wire detection phase. Hereinafter, each phase will be described in detail.

### [Conductivity Inspection Phase]

In the method of determining a possibly-unused electric wire according to the embodiment of the present invention, the continuity inspection phase has a formation step of forming one pattern by assigning a wire harness with an arbitrary part number out of wire harnesses routed in each of divided regions into which the space of a vehicle is divided, and a classification step of classifying for each pattern a group of electric wires of a first wire harness assigned to a first divided region of the divided regions into a necessary electric wire having a connection counterpart in a second divided region adjacent to the first divided region among the divided regions, and into an extra electric wire not having a connection counterpart in the second divided region. For example, the continuity inspection phase is equivalent to a wire harness continuity inspection method disclosed in JP-A-2011-137800 filed by the applicant of this application.

Refer to paragraphs [0043] to [0180] of the description of JP-A-2011-137800 for the formation step of the continuity inspection phase. Refer to paragraphs [0143] to [0170] of the description of JP-2011-137800 for the classification step of the continuity inspection phase.

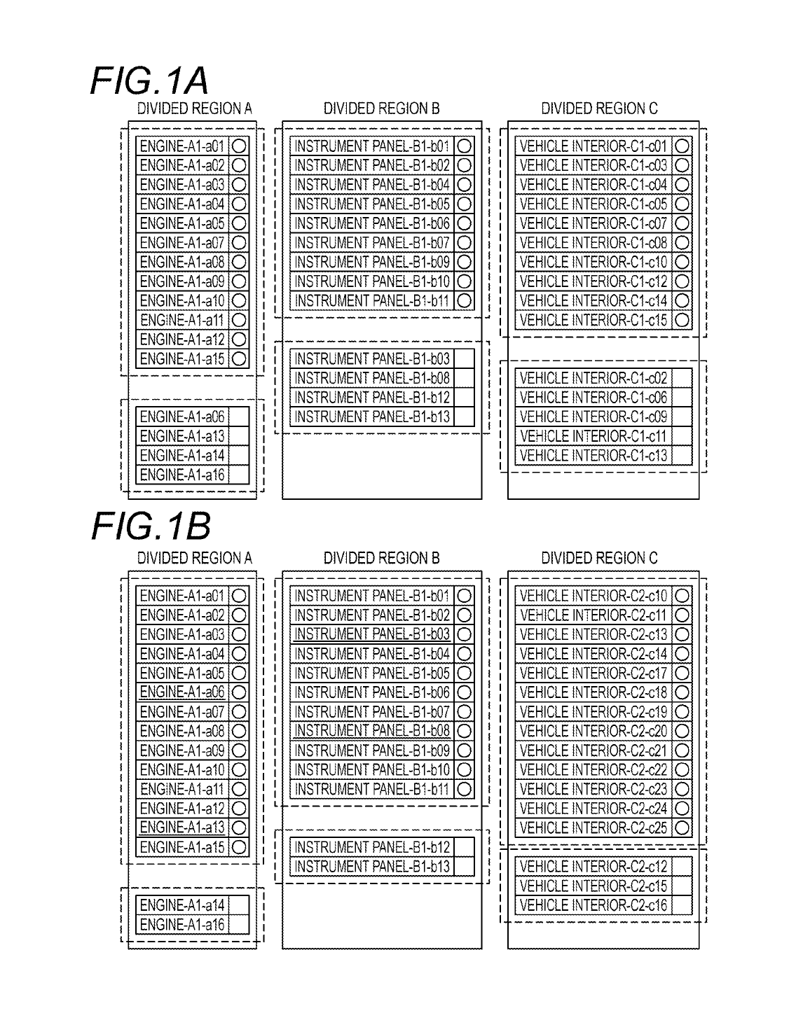

When the classification step is completely executed for one partial connector and wiring pattern, an inspection history is recorded for each of the inspected electric wires of a wire harness. FIG. 1A shows tables illustrating recorded data after the continuity inspection phase for one pattern is completed, in the method of determining a possibly-unused electric wire according to the embodiment of the present invention. In FIG. 1A, the space of a vehicle is assumably divided into three divided regions.

As illustrated in FIG. 1A, inspection histories are recorded for each of divided regions A, B, and C. An inspection history contains information regarding a continuity inspection target, and a continuity inspection result for the continuity inspection target. In FIG. 1A, for descriptive purposes, a continuity inspection target is denoted with “XXXX-YY-ZZZ”, in which “XXXX” refers to an identifier for identifying a divided region, “YY” refers to an identifier for identifying the part number of a wire harness that can be routed in a divided region identified by “XXXX”, and “ZZZ” refers to an identifier for identifying an electric wire installed in a divided region identified by “XXXX”. In the example of the divided region A, since the divided region A is an engine compartment, a string of characters like “engine” are written in “XXXX”, and since a wire harness with a part number “A1” is assigned to the divided region A, “A1” is written in “YY”, and each of electric wire identifiers “a01” to “a16” is written in “ZZZ” as electric wire identification information. A continuity inspection target is uniquely selected by designating a divided region identifier, a wire harness part number identifier, and an electric wire identifier. Twenty-five types of electric wires “a01” to “a25” can be installed in the divided region A. For this reason, the wire harness with the part number “A1” assigned to the divided region “engine” includes the electric wires “a01” to “a16” among the electric wires “a01” to “a25”.

In addition, a continuity inspection result for each continuity inspection target is recorded in association with the continuity inspection target. In FIG. 1A, for descriptive purposes, a continuity inspection result is indicated by two denotative signs “◯” and “blank space”. The sign “◯” means that the continuity of an associated continuity inspection target is successfully inspected, and “blank space” means that a continuity inspection result is not recorded in association with a continuity inspection target, that is, the continuity of a continuity inspection target is not inspected. In FIG. 1A, the continuity inspection targets successfully inspected for continuity, and the continuity inspection targets not inspected for continuity are arranged sequentially from the top to the bottom. From the inspection histories in the divided region A, it is understood that in the wire harness with the part number “A1” assigned to the divided region “engine”, 12 electric wires are successfully inspected for continuity and have the respective connection counterparts, and four electric wires do not have the respective recorded continuity inspection results and do not have the respective connection counterparts. As a result, in the wire harness with the part number “A1” assigned to the divided region “engine”, the four electric wires not having the respective recorded continuity inspection results may be possibly-unused electric wires.

In the example of the divided region B, since the divided region B is an instrument panel, a string of characters like “instrument panel” are written in “XXXX”, and since a wire harness with a part number “B1” is assigned to the divided region B, “B1” is written in “YY”, and each of electric wire identifiers “b01” to “b13” is written in “ZZZ” as electric wire identification information. Twenty-five types of electric wires “b01” to “b25” can be installed in the divided region B. For this reason, the wire harness with the part number “B1” assigned to the divided region “instrument panel” includes the electric wires “b01” to “b13” among the electric wires “b01” to “b25”. In FIG. 1A, also in the divided region B, the continuity inspection targets successfully inspected for continuity, and the continuity inspection targets not inspected for continuity are arranged sequentially from the top to the bottom. From the inspection histories in the divided region B, it is understood that in the wire harness with the part number “B1” assigned to the divided region “instrument panel”, nine electric wires are successfully inspected for continuity and have the respective connection counterparts, and four electric wires do not have the respective recorded continuity inspection results and do not have the respective connection counterparts. As a result, in the wire harness with the part number “B1” assigned to the divided region “instrument panel”, the four electric wires not having the respective recorded continuity inspection results may be possibly-unused electric wires.

In the example of the divided region C, since the divided region C is a vehicle interior, a string of characters like “vehicle interior” are written in “XXXX”, and since a wire harness with a part number “C1” is assigned to the divided region C, “C1” is written in “YY”, and each of electric wire identifiers “c01” to “c15” is written in “ZZZ” as electric wire identification information. Twenty-five types of electric wires “c01” to “c25” can be installed in the divided region C. For this reason, the wire harness with the part number “C1” assigned to the divided region “vehicle interior” includes the electric wires “c01” to “c15” among the electric wires “c01” to “c25”. In FIG. 1A, also in the divided region C, the continuity inspection targets successfully inspected for continuity, and the continuity inspection targets not inspected for continuity are arranged sequentially from the top to the bottom. From the inspection histories in the divided region C, it is understood that in the wire harness with the part number “C1” assigned to the divided region “vehicle interior”, ten electric wires are successfully inspected for continuity and have the respective connection counterparts, and four electric wires do not have the respective recorded continuity inspection results and do not have the respective connection counterparts. As a result, in the wire harness with the part number “C1” assigned to the divided region “vehicle interior”, the four electric wires not having the respective recorded continuity inspection results may be possibly-unused electric wires.

Hereinafter, the following description with reference to FIG. 1B is regarding recorded inspection histories when the classification step is completely executed for another partial connector and wiring pattern. FIG. 1B shows tables illustrating the recorded data after a continuity inspection phase for the other connector and wiring pattern is completed, in the method of determining a possibly-unused electric wire according to the embodiment of the present invention. The inspection histories described with reference to FIG. 1A are for the partial connector and wiring pattern in which the wire harness with the part number “A1” is assigned to the divided region A, the wire harness with the part number “B1” is assigned to the divided region B, and the wire harness with the part number “C1” is assigned to the divided region B. FIG. 1B illustrates the inspection histories for the case in which the wire harness assigned to the divided region C has a different part number, and illustrates the inspection histories for a partial connector and wiring pattern in which the wire harness with the part number “A1” is assigned to the divided region A, the wire harness with the part number “B1” is assigned to the divided region B, and a wire harness with a part number “C2” is assigned to the divided region C.

The wire harness with the same part number “A1” as in the description of FIG. 1A is assigned to the divided region A. For this reason, the wire harness with the part number “A1” assigned to the divided region “engine” includes the electric wires “a01” to “a16”. From the inspection histories in the divided region A, it is understood that in the wire harness with the part number “A1” assigned to the divided region “engine”, fourteen electric wires are successfully inspected for continuity and have the respective connection counterparts, and two electric wires do not have the respective recorded continuity inspection results and do not have the respective connection counterparts. As a result, in the wire harness with the part number “A1” assigned to the divided region “engine”, the two electric wires not having the respective recorded continuity inspection results may be possibly-unused electric wires.

The wire harness with the same part number “B1” as in the description of FIG. 1A is assigned to the divided region B. For this reason, the wire harness with the part number “B1” assigned to the divided region “instrument panel” includes the electric wires “b01” to “b13”. From the inspection histories in the divided region B, it is understood that in the wire harness with the part number “B1” assigned to the divided region “instrument panel”, eleven electric wires are successfully inspected for continuity and have the respective connection counterparts, and two electric wires do not have the respective recorded continuity inspection results and do not have the respective connection counterparts. As a result, in the wire harness with the part number “B1” assigned to the divided region “instrument panel”, the two electric wires not having the respective recorded continuity inspection results may be possibly-unused electric wires.

The part number “C2” of the wire harness assigned to the divided region C is different from that of the wire harness described in FIG. 1A. The wire harness with the part number “C2” assigned to the divided region “vehicle interior” includes the electric wires “c10” to “b25” among the electric wires “c01” to “c25”. From the inspection histories in the divided region C, it is understood that in the wire harness with the part number “C2” assigned to the divided region “vehicle interior”, thirteen electric wires are successfully inspected for continuity and have the respective connection counterparts, and three electric wires do not have the respective recorded continuity inspection results and do not have the respective connection counterparts.

As can be understood from a comparison between the respective inspection histories illustrated in FIGS. 1A and 1B, when the continuity of an electric wire is inspected for different partial connector and wiring patterns, the respective inspection histories for the partial connector and wiring patterns are different from each other even though a wire harness with the same part number is assigned to a divided region for the patterns. For example, as illustrated in FIG. 1A, according to the inspection histories after the continuity inspection phase for a connector and wiring pattern is completed, the continuity of twelve electric wires is successfully inspected in the divided region A. In contrast, as illustrated in FIG. 1B, according to the inspection histories after the continuity inspection phase for another connector and wiring pattern is completed, the continuity of fourteen electric wires is successfully inspected in the divided region A. Similarly, as illustrated in FIG. 1A, the continuity of nine electric wires is successfully inspected in the divided region B. In contrast, as illustrated in FIG. 1B, the continuity of eleven electric wires is successfully inspected in the divided region B. The reason for an increase (or a decrease) in the number of electric wires successfully inspected for continuity is because the number of specifications for the other connector and wiring pattern is greater than (or less than) that for the one pattern, and the number of electric wires (electric wires being connected to electric circuits for realizing the specifications) for the other pattern is greater than (or less than) that for the connector and wiring pattern.

As described above with reference to FIGS. 1A and 1B, a continuity inspection phase has the formation step of forming one pattern by assigning a wire harness with an arbitrary part number out of wire harnesses routed in each of divided regions into which the space of a vehicle is divided, and a classification step of classifying a group of electric wires of a first wire harness assigned to a first divided region of the divided regions into a necessary electric wire having a connection counterpart in a second divided region adjacent to the first divided region among the divided regions, and into an extra electric wire not having a connection counterpart in the second divided region, for each pattern. Hereinafter, an electric wire having a successful continuity inspection result may be referred to as a necessary electric wire, and an electric wire not having a recorded continuity inspection result may be referred to as an extra electric wire.

The continuity inspection phase of the method of determining a possibly-unused electric wire according to the embodiment of the present invention is one embodiment of the wire harness continuity inspection method disclosed in JP-A-2011-137800; however, the present invention is not limited to that embodiment. The following technique can be applied to the present invention: the technique of being able to classify a group of electric wires of a first wire harness (a wire harness being assigned to a first divided region of divided regions) into a necessary electric wire having a connection counterpart in a second divided region adjacent to a first divided region among the divided regions, and into an extra electric wire not having a connection counterpart in the second divided region, for each pattern.

### [Possibly-Unused Electric Wire Detection Phase]

The description given up to now with reference to FIGS. 1A and 1B is regarding the recorded inspection histories when the classification step is completely executed for a partial connector and wiring pattern. As described above, when the classification step is completely executed, a wire harness with a predetermined part number assigned to each of the divided regions A, B, and C may have extra electric wires. The extra electric wires may contain a possibly-unused electric wire. It is not possible to conclude that the entirety of the extra electric wires are possibly-unused electric wires, and the reason for this is because the extra electric wires may contain electric wires not used for the entirety of the connector and wiring patterns, in other words, the extra electric wires are included in the entirety of wire harnesses with the respective part numbers in a divided region, but may contain electric wires which are not used. For this reason, when electric wires are determined to be extra electric wires in the continuity inspection for a partial connector and wiring pattern, until the continuity of the electric wires is successfully inspected for another partial connector and wiring pattern, and the electric wires are confirmed as necessary electric wires, it is not possible to determine that the electric wires are possibly-unused electric wires. Hereinafter, the possibly-unused electric wire detection phase will be described in detail in a case in which a possibly-unused electric wire is specified among extra electric wires.

### [Basic Example of Possibly-Unused Electric Wire Detection Phase]

First, a basic example of the possibly-unused electric wire detection phase will be described with reference to FIGS. 1A and 1B. According to the inspection histories illustrated in FIG. 1A, the wire harness with the part number “A1” assigned to the divided region “engine” contains four extra electric wires “engine-A1-a06”, “engine-A1-a13”, “engine-A1-a14”, and “engine-A1-a16”. From the inspection histories illustrated in FIG. 1B, it can be understood that two electric wires “engine-A1-a06” and “engine-A1-a13” between the four extra electric wires are the necessary electric wires of the wire harness with the part number “A1” assigned to the divided region “engine”. For this reason, two electric wires “engine-A1-a06” and “engine-A1-a13” (electric wires being determined to be the extra electric wires according to the inspection histories illustrated in FIG. 1A) are specified as possibly-unused electric wires.

Similarly, according to the inspection histories illustrated in FIG. 1A, the wire harness with the part number “B1” assigned to the divided region “instrument panel” contains four extra electric wires “instrument panel-B1-b03”, “instrument panel-B1-b08”, “instrument panel-B1-b12”, and “instrument panel-B1-b13”. From the inspection histories illustrated in FIG. 1B, it can be understood that two electric wires “instrument panel-B1-b03” and “instrument panel-B1-b08” between the four extra electric wires are the necessary electric wires of the wire harness with the part number “B1” assigned to the divided region “instrument panel”. For this reason, two electric wires “instrument panel-B1-b03” and “instrument panel-B1-b08” (electric wires being determined to be the extra electric wires according to the inspection histories illustrated in FIG. 1A) are specified as possibly-unused electric wires.

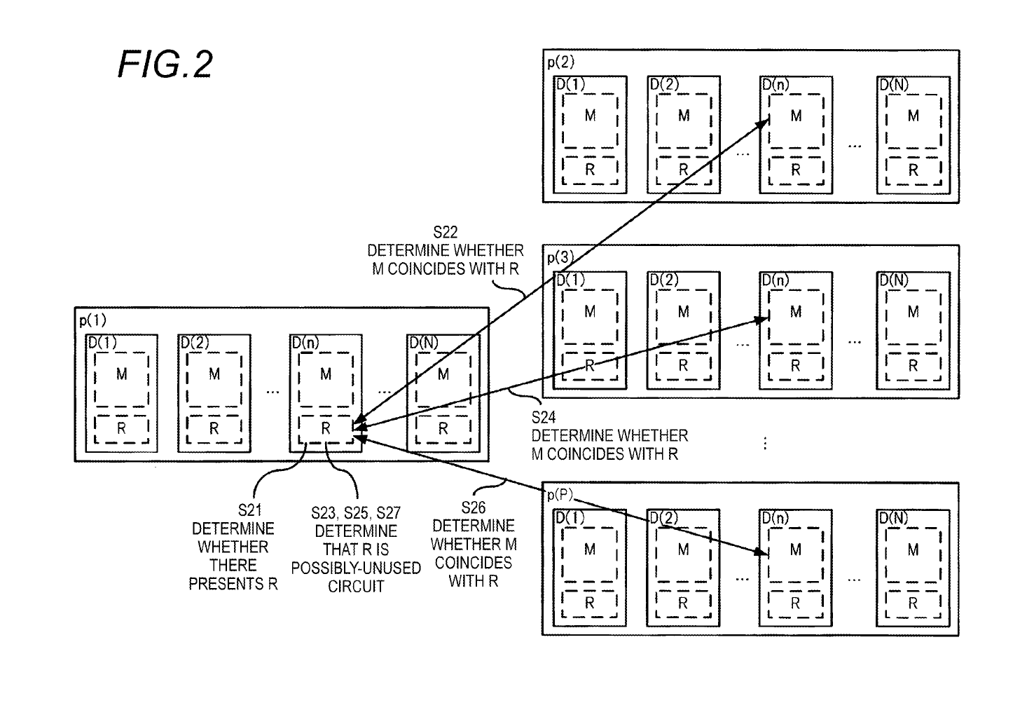

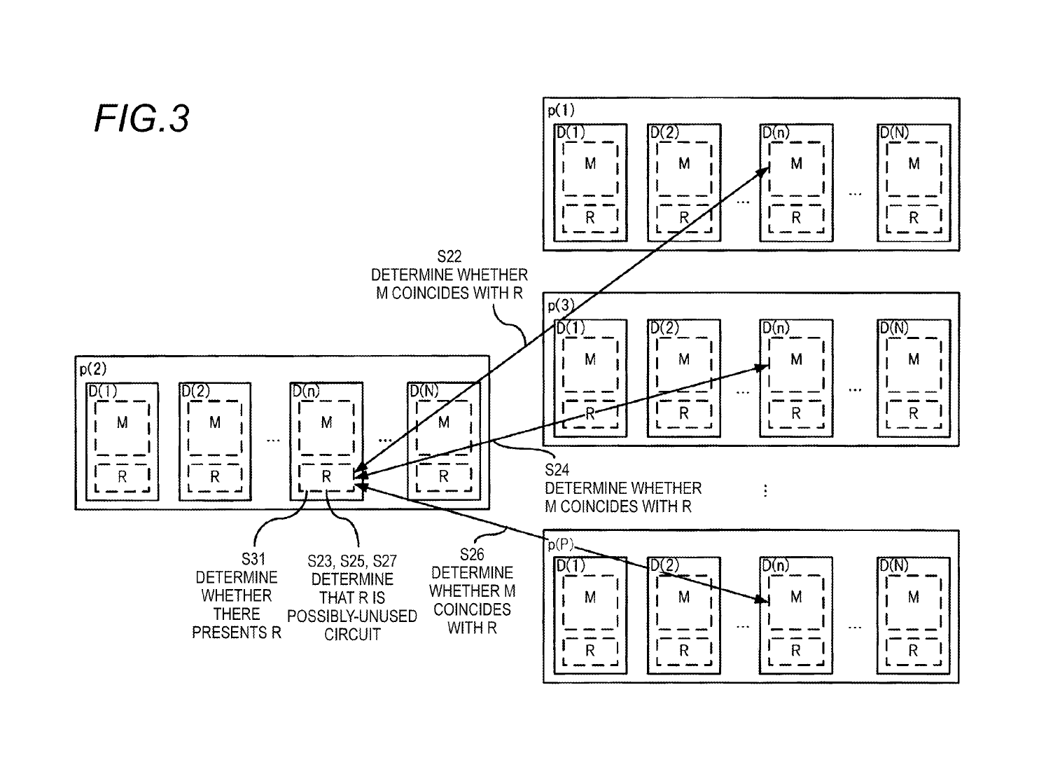

As such, when electric wires are determined to be extra electric wires for a predetermined divided region in a continuity inspection for a partial connector and wiring pattern, and the extra electric wires are determined to be necessary electric wires for the predetermined divided region in a continuity inspection for another partial connector and wiring pattern, the electric wires are determined to be possibly-unused electric wires. In contrast, when electric wires are determined to be extra electric wires for a predetermined divided region in a continuity inspection for a partial connector and wiring pattern, and the extra electric wires are not determined to be necessary electric wires for the predetermined divided region in a continuity inspection for another partial connector and wiring pattern, the electric wires are not determined to be possibly-unused electric wires. The method of determining a possibly-unused electric wire will be described with reference to FIGS. 2 and 3. FIGS. 2 and 3 are diagrams illustrating the possibly-unused electric wire detection phase in the method of determining a possibly-unused electric wire according to the embodiment of the present invention.

As illustrated in FIG. 2, after the continuity inspection phase is completed, the inspection histories of the continuity inspection for P (the total number of patterns) partial connector and wiring patterns are recorded. Here, a vehicle, that is, an inspection target in the continuity inspection phase, has N divided regions, and the divided regions are respectively denoted with D(1), D(2), . . . D(n), . . . D(N) (here, N is a natural number). When the total number of part numbers of wire harnesses assigned to the divided region D(n) is W(n), P (the total number of partial connector and wiring patterns inspected for continuity in the continuity inspection phase) is calculated by expression P=W(1)×W(2)× . . . ×W(N). In addition, p(x) is used so as to denote an x-th pattern among P (the total number of patterns) patterns (here, x is 1, 2, . . . x, . . . P). In the inspection histories of a continuity inspection for the x-th partial connector and wiring pattern p(x), a necessary electric wire and an extra electric wire of a wire harness assigned to the divided region D(n) are respectively denoted with M and R.

Subsequently, an algorithm which determines a possibly-unused electric wire will be described. The algorithm determines whether a possibly-unused electric wire exists in the wire harness assigned to the divided region D(n).

First, with reference to the inspection histories of a continuity inspection for a first connector and wiring pattern p(1), it is determined whether extra electric wires R exist in a wire harness assigned to the divided region D(n) (step S21). When it is determined that there are no extra electric wires R present (NO in step S21), as illustrated in FIG. 3, with reference to the inspection histories of a continuity inspection for a second connector and wiring pattern p(2) which is a subsequent pattern to the first connector and wiring pattern, it is determined whether extra electric wires R exist in a wire harness assigned to the divided region D(n) (step S31).

In contrast, when it is determined that there are the extra electric wires R present in the wire harness assigned to the divided region D(n) for the first pattern p(1) (YES in step S21), subsequently, with reference to the inspection histories of the continuity inspection for the second connector and wiring pattern p(2), it is determined whether necessary electric wires M assigned to the divided region D(n) for the second pattern p(2) coincide with the extra electric wires R assigned to the divided region D(n) for the first pattern p(1) (step S22). When any of the necessary electric wires M coincides with any of the extra electric wires R (YES in step S22), the coincident extra electric wires R are determined to be possibly-unused electric wires (step S23).

In contrast, when there is no coincidence present between the necessary electric wires M and the extra electric wires R in step S22, and subsequent to step S23, the remainder of the extra electric wires R assigned to the divided region D(1) for the first pattern p(1) still contains electric wires which are not determined to be possibly-unused electric wires, subsequently, with reference to the inspection histories of a continuity inspection for a third connector and wiring pattern p(3), it is determined whether necessary electric wires M assigned to the divided region D(n) for the third pattern p(3) coincide with the extra electric wires R assigned to the divided region D(n) for the first pattern p(1) (step S24). When any of the necessary electric wires M coincides with any of the extra electric wires R (YES in step S24), the coincident extra electric wires R are determined to be possibly-unused electric wires (step S25).

Thereafter, when there is no coincidence present between the necessary electric wires M and the extra electric wires R, and the remainder of the extra electric wires R assigned to the divided region D(1) for the first pattern p(1) contains electric wires which are not determined to be possibly-unused electric wires, while sequentially referring to the respective inspection histories for patterns p(4), p(5) . . . p(P), it is repeatedly determined whether necessary electric wires M assigned to the divided region D(n) for the x-th pattern p(x) coincide with the extra electric wires R assigned to the divided region D(n) for the first pattern p(1) (step S26). When the remainder of the extra electric wires R assigned to the divided region D(1) for the first pattern p(1) contains electric wires which are not determined to be possibly-unused electric wires, a series of these processes is repeated. When necessary electric wires M assigned to the divided region D(n) for a final P-th pattern p(P) do not coincide with the extra electric wires R assigned to the divided region D(n) for the first pattern p(1), the extra electric wires R are not determined to be possibly-unused electric wires (step S27). In contrast, when the entirety of the extra electric wires R assigned to the divided region D(1) for the first pattern p(1) are determined to be possibly-unused electric wires in the middle of a series of these processes, as illustrated in FIG. 3, subsequently, with reference to the inspection histories of the continuity inspection for the second partial connector and wiring pattern p(2), it is determined whether there are the extra electric wires R present in the wire harness assigned to the divided region D(n) (step S31). Thereafter, the processes of steps S22 to S27 are executed for the extra electric wires R assigned to the divided region D(n) for the second pattern p(2), that is, while sequentially referring to the respective inspection histories of the first pattern p(1), the third pattern p(3), the fourth pattern p(4), . . . the P-th pattern p(P) (here, the second pattern p(2) is excluded), it is repeatedly determined whether necessary electric wires M assigned to the divided region D(n) for the x-th pattern p(x) coincide with the extra electric wires R assigned to the divided region D(n) for the second pattern p(2) (refer to FIG. 3), and possibly-unused electric wires are specified from the extra electric wires R. In addition, the processes of steps S22 to S27 are executed for the extra electric wires R assigned to the divided region D(n) for each of the third pattern p(3), the fourth pattern p(4), . . . the P-th pattern p(P), and possibly-unused electric wires are specified from the extra electric wires R.

As such, with reference to the respective inspection histories of the continuity inspections for the entirety of the first partial connector and wiring pattern p(1) to the P-th partial connector and wiring pattern p(P), it is determined whether electric wires coincide with extra electric wires R assigned to the divided region D(n) for a pattern, but do not coincide with necessary electric wires M assigned to the divided region D(n) for each of the patterns other than the pattern.

As such, according to the method of determining a possibly-unused electric wire of the present invention, it is possible to specify possibly-unused electric wires from a group of electric wires of a wire harness via analysis. When a general-purpose wire harness including electric wires compatible for the entirety of a given number of combinations is adopted so as to reduce part number management costs, it is effective to determine whether a group of electric wires of the wire harness contain possibly-unused electric wires. When true possibly-unused electric wires are specified, in other words, non-true possibly-unused electric wires are specified due to the inaccuracy of the auxiliary device wiring information and the partial connector and wiring information, the non-true possibly-unused electric wires are removed from the wire harness, and thereby it is possible to realize a reduction in the cost and the weight of the wire harness.

### [Application Example 1 of Possibly-Unused Electric Wire Detection Phase]

In the [Basic Example of Possibly-unused electric wire Detection Phase], the basic algorithm of the method of determining a possibly-unused electric wire has been described. Hereinafter, application examples of the basic algorithm of the method of determining a possibly-unused electric wire will be described.

According to the algorithm described in the [Basic Example of Possibly-unused electric wire Detection Phase], when one electric wire of extra electric wires assigned to a predetermined divided region for a pattern is assigned as an extra electric wire to the predetermined divided region for another pattern, it is determined whether the electric wire is a possibly-unused electric wire for each pattern.

The following process is added to each of steps S23, S25, and S27: process of listing extra electric wires R that are determined or are not determined to be possibly-unused electric wires for a pattern, and updating the listed data whenever it is determined that new extra electric wires R are determined or are not determined to be possibly-unused electric wires. In steps S22, S24, and S26, it is determined whether extra electric wires coincide or do not coincide with the data listed in steps S23, S25, and S27 before the determination is made with reference to the inspection histories of a continuity inspection for a partial connector and wiring pattern p(x). In steps S22, S24, and S26, with reference to the inspection histories of the continuity inspection for the partial connector and wiring pattern p(x), it is determined whether the necessary electric wires M assigned to the divided region D(n) for the pattern p(x) coincide with the electric wires of the extra electric wires R (electric wires being targets for determining possibly-unused electric wires), which do not coincide with the listed data. When the coincident extra electric wires R are determined to be possibly-unused electric wires in step S22, S24, and S26, the listed data is updated in step S23, S25, and S27.

As such, since a result is determined with reference to the listed data before the determination is made with reference to the inspection histories of the continuity inspection for the partial connector and wiring pattern p(x), the processes of determining whether extra electric wires are disposal electric wires are not required to be executed plural times. As a result, it is possible to improve analysis efficiency for the possibly-unused electric wire detection phase.

The non-possibly-unused electric wires are not the necessary electric wires M in the inspection histories of a continuity inspection for any one of the partial connector and wiring patterns. For this reason, the non-possibly-unused electric wires are the remaining electric wires other than the necessary electric wires assigned to the divided region D(n) for the pattern p(x). Hereinafter, Application Example 2 of the possibly-unused electric wire detection phase will be described.

### [Application Example 2 of Possibly-Unused Electric Wire Detection Phase]

According to the algorithm described in the [Basic Example of Possibly-unused electric wire Detection Phase], in steps S22, S24, and S26, when the extra electric wires R (the electric wires being targets for determining the possibly-unused electric wires) in the divided region D(n) for a pattern p(x) are retrieved from the necessary electric wires M assigned to the divided region D(n) for patterns other than the pattern p(x), the following two condition coincidence techniques are considered. That is,

(A) The technique of determining whether part number identifiers coincide with each other, and determining whether electric wire identifiers coincide with each other when the part number identifiers coincide with each other.

(B) The technique of determining whether electric wire identifiers coincide with each other, and determining whether part number identifiers coincide with each other when the electric wire identifiers coincide with each other. When any one of the condition coincidence techniques is adopted, the same determination result is obtained in each of steps S23, S25, and S27.

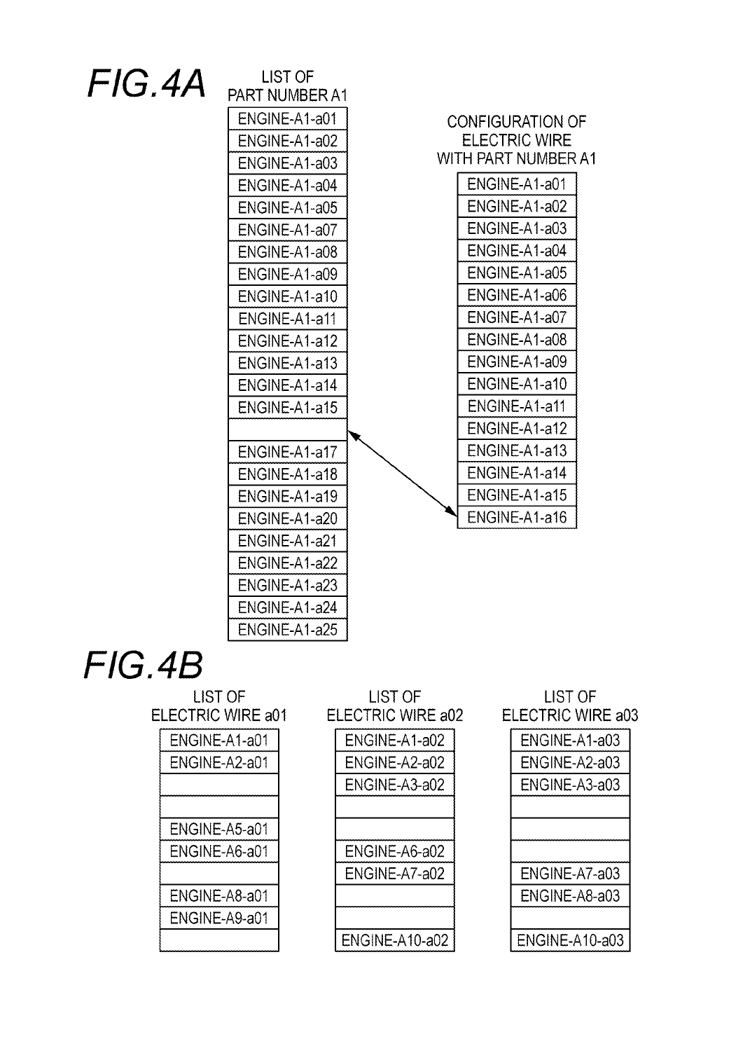

Here, when the condition coincidence technique described in (A) is adopted, the following process is added to each of steps S22, S24, and S26: process of listing coincident part number identifiers, and updating the listed data whenever a part number identifier is detected. When it is completely determined whether extra electric wires R assigned for a pattern are possibly-unused electric wires, as illustrated in FIG. 4A, necessary electric wires M assigned for any one of patterns are listed for the part number of the wire harness including the extra electric wires R. For example, FIG. 4A illustrates the listed data when it is determined whether the wire harness with the part number “A1” assigned to the divided region “engine” for a pattern contains possibly-unused electric wires. According to the left side table illustrated in FIG. 4A, in the wire harness with the part number “A1”, the electric wires “engine-A1-a01” to “engine-A01-a15”, and the electric wires “engine-A1-a17” to “engine-A1-a25” are respectively the necessary electric wires M assigned for any one of patterns. When the listed data is compared to the electric wires (electric wires being listed in the right side table in FIG. 4A) of the wire harness with the part number, it is possible to determine that electric wires not in the listed data are not possibly-unused electric wires in the wire harness with the part number. In FIG. 4A, it can be understood that the electric wire “engine-A1-a16” is not a possibly-unused electric wire. It is possible to easily find out which electric wires of a wire harness with a predetermined part number are useless due to the list of the data.

In contrast, when the condition coincidence technique described in

(B) is adopted, the following process is added to each of steps S22, S24, and S26: process of listing coincident electric wire identifiers, and updating the listed data whenever an electric wire identifier is detected. When it is completely determined whether extra electric wires R assigned for a pattern are possibly-unused electric wires, as illustrated in FIG. 4B, necessary electric wires M assigned for any one of patterns are listed for the electric wire identifier of each of the extra electric wires R. For example, FIG. 4B illustrates the listed data when it is determined whether the wire harnesses with the respective part numbers “A1” to “A10” assigned to the divided region “engine” for a pattern contain possibly-unused electric wires. As illustrated in FIG. 4B, the electric wire identifier “a01” is used for the part numbers “A1”, “A2”, “A5”, “A6”, “A8”, and “A9”, the electric wire identifier “a02” is used for the part numbers “A1”, “A2”, “A3”, “A6”, “A7”, and “A10”, and the electric wire identifier “a03” is used for the part numbers “A1”, “A2”, “A3”, “A7”, “A8”, and “A10”. It is possible to specify the part number of a wire harness containing an electric wire with a specific identifier with reference to the listed data. When the identifiers of electric wires contained in the extra electric wires R coincide with the listed data, and the data does not contain the part number of the wire harness including the electric wires, it is possible to determine that electric wires specified by the identifiers are not possibly-unused electric wires. It is possible to easily find out which part number is used for a predetermined electric wire of a wire harness due to the list of the data.

### [Application Example 3 of Possibly-Unused Electric Wire Detection Phase]

According to the algorithm described in the [Basic Example of Possibly-unused electric wire Detection Phase], it is determined whether each electric wire of the extra electric wires R is or is not a possibly-unused electric wire. In particular, in the method of determining a possibly-unused electric wire of the present invention, it is important to specify electric wires which are not possibly-unused electric wires among the extra electric wires R. The electric wires not specified as possibly-unused electric wires in this manner are not used in any wire harness with a part number which connects electric components, are useless electric wires, and are required to be removed from the wire harness. Hereinafter, a technique of effectively specifying non-possibly-unused electric wires from extra electric wires R will be described.

According to the algorithm described in the [Basic Example of Possibly-unused electric wire Detection Phase], it is determined whether the extra electric wires R (the electric wires being targets for determining the possibly-unused electric wires) assigned for a pattern p(x) coincide with the necessary electric wires M assigned for patterns other than the pattern p(x), and thereby the extra electric wires R respectively coincident with the necessary electric wires M are determined to be possibly-unused electric wires, and the extra electric wires R respectively non-coincident with the necessary electric wires M are not determined to be possibly-unused electric wires. In contrast, according to the algorithm described in the [Application Example 2 of Possibly-unused Electric Wire Detection Phase], non-possibly-unused electric wires are specified without reference to the extra electric wires R and with reference to only the necessary electric wires M.

The non-possibly-unused electric wires are not the necessary electric wires M in the inspection histories of the continuity inspection for any one of the partial connector and wiring patterns. For this reason, the non-possibly-unused electric wires are the remaining electric wires other than the necessary electric wires assigned to the divided region D(n) for the pattern p(x). It is possible to specify non-possibly-unused electric wires in this manner.

### [Configuration of Wire Harness Continuity Inspection Apparatus]

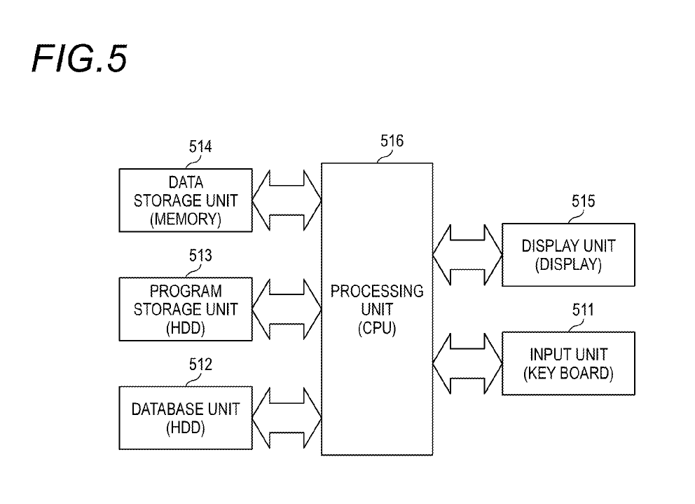

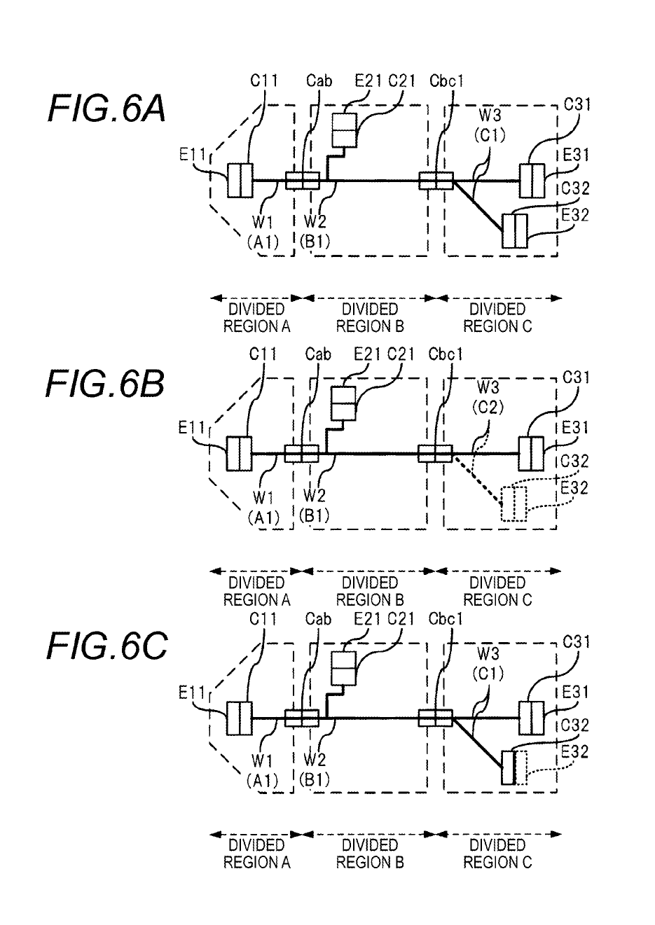

The following description with reference to FIG. 5 is regarding a wire harness continuity inspection apparatus that executes the method of determining a possibly-unused electric wire according to the embodiment of the present invention. FIG. 5 is a functional block diagram of the apparatus that executes the method of determining a possibly-unused electric wire according to the embodiment of the present invention.

The wire harness continuity inspection apparatus according to the embodiment of the present invention includes an input unit 511; a database unit 512; a program storage unit 513; a data storage unit 514; a display unit 515; and a processing unit 516. For example, when the wire harness continuity inspection apparatus of the present invention is configured by a general-purpose PC, the input unit 511 is realized by various input interfaces such as a key board, a mouse, and a ten key pad, the database unit 512 and the program storage unit 513 are realized by a hard disc drive (HDD), the data storage unit 514 is realized by a random access memory (RAM), the display unit 515 is realized by various output devices such as a CRT display or a liquid crystal display, and the processing unit 516 is realized by a central processing unit (CPU). The database unit 512 stores auxiliary device wiring data and partial connector and wiring data (as necessary, data for an actual wiring diagram prepared based on the auxiliary device wiring information), and data for auxiliary device specifications. The program storage unit 513 stores a program that causes the processing unit 516 to execute the [Continuity Inspection Phase] and the [Possibly-unused electric wire Detection Phase]. The data storage unit 514 stores data input and output from the processing unit 516 that execute the [Continuity Inspection Phase] and the [Possibly-unused electric wire Detection Phase].

Here, the characteristics of the method and the program for determining a possibly-unused electric wire according to the embodiment of the present invention will be briefly summarized in the following configurations [1] to [3].
[1] A method of determining a possibly-unused electric wire, the method including:
   a formation step of forming one pattern by assigning a wire harness with an arbitrary part number out of wire harnesses routed in each of divided regions into which a space of a vehicle is divided;
   a classification step of classifying for each pattern a group of electric wires of a first wire harness assigned to a first divided region of the divided regions into a necessary electric wire having a connection counterpart in a second divided region adjacent to the first divided region among the divided regions, and into an extra electric wire not having a connection counterpart in the second divided region; and
   a determination step of determining that an electric wire is a possibly-unused electric wire when the electric wire is classified as the extra electric wire in any one of the patterns and classified as the necessary electric wire in any one of the remaining patterns, and determining that an electric wire is not a possibly-unused electric wire when the electric wire is classified as the extra electric wire in entirety of the patterns.
[2] The method of determining the possibly-unused electric wire according to the configuration [1], wherein when an electric wire is classified as the extra electric wire for the first wire harness with a predetermined part number assigned to one or a plurality of the patterns, and is classified as the necessary electric wire for the first wire harness with the predetermined part number assigned to one or a plurality of the remaining patterns, the electric wire is determined to be a possibly-unused electric wire in the determination step.
[3] A program that causes a computer to execute each step in the method of determining the possibly-unused electric wire described in the configuration [1] or [2].

The present invention has been described in detail and with reference to the specific embodiment; however, it is apparent to persons skilled in the art that modifications and corrections can be made to the present invention in various forms insofar as the modifications and the corrections do not depart from the philosophy and the scope of the present invention.

According to the method and the program for determining a possibly-unused electric wire of the present invention, it is possible to specify possibly-unused electric wires from a group of electric wires of a wire harness via analysis. The present invention having these effects is effective to determining the existence and non-existence of possibly-unused electric wires.

What is claimed is:

1. A method of determining a possibly-unused electric wire, the method comprising:
a formation step of forming one pattern by assigning a wire harness with an arbitrary part number out of wire harnesses routed in each of divided regions into which a space of a vehicle is divided;
a classification step of classifying for each pattern a group of electric wires of a first wire harness assigned to a first divided region of the divided regions into a necessary electric wire having a connection counterpart in a second divided region adjacent to the first divided region among the divided regions, and into an extra electric wire not having a connection counterpart in the second divided region; and
a determination step of determining that an electric wire is a possibly-unused electric wire when the electric wire is classified as the extra electric wire in any one of the patterns and classified as the necessary electric wire in any one of the remaining patterns, and determining that an electric wire is not a possibly-unused electric wire when the electric wire is classified as the extra electric wire in entirety of the patterns.

2. The method of determining the possibly-unused electric wire according to claim 1, wherein
the determination step includes determining that an electric wire is a possibly-unused electric wire when the electric wire is classified as the extra electric wire for the first wire harness with a predetermined part number assigned to one or a plurality of the patterns and classified as the necessary electric wire for the first wire harness with the predetermined part number assigned to one or a plurality of the remaining patterns.

3. A computer-readable storage medium in which is stored a program that causes a computer to execute each step in the method of determining the possibly-unused electric wire according to claim 1.
